(19) United States
(12) Patent Application Publication
(10) Pub. No.: US 2022/0235248 A1
(43) Pub. Date: Jul. 28, 2022

(54) METAL PARTICLES FOR ADHESIVE PASTE, SOLDER PASTE COMPOSITION INCLUDING THE SAME, AND METHOD OF PREPARING METAL PARTICLES FOR ADHESIVE PASTE

(71) Applicant: Samsung Electronics Co., Ltd., Suwon-si (KR)

(72) Inventors: Junghoon LEE, Seongnam-si (KR); Byonggwon SONG, Seoul (KR); Kunmo CHU, Seoul (KR)

(73) Assignee: Samsung Electronics Co., Ltd., Suwon-si (KR)

(21) Appl. No.: 17/490,346

(22) Filed: Sep. 30, 2021

(30) Foreign Application Priority Data
Jan. 26, 2021 (KR) 10-2021-0011038

(51) Int. Cl. C09J 11/04; B23K 35/02; B22F 1/02; B23K 35/26

(52) U.S. Cl. CPC C09J 11/04; B23K 35/025; B23K 2103/08; B23K 35/262; B22F 2304/10; B22F 1/025

(57) ABSTRACT

Provided are metal particles for an adhesive paste, a solder paste composition including the same, and a method of preparing the metal particles for an adhesive paste. The metal particles for an adhesive paste may include a core including one or more metal materials; and a shell arranged on part or an entirety of the core and including one or more metal materials. The metal material of the core may have a melting point higher than that of the metal material of the shell. An intermetallic compound is capable of being formed between the metal material of the core and the metal material of the shell. A ratio (D90/D10) of the 90% cumulative mass particle size distribution (D90 size) to the 10% cumulative mass particle size distribution (D10 size) in a particle size distribution of the metal particles may be 1.22 or less.

### CROSS-REFERENCE TO RELATED APPLICATION

This application is based on and claims priority under 35 U.S.C. § 119 to Korean Patent Application No. 10-2021-0011038, filed on Jan. 26, 2021, in the Korean Intellectual Property Office, the disclosure of which is incorporated by reference herein in its entirety.

### BACKGROUND

### 1. Field

The present disclosure relates to metal particles for an adhesive paste, a solder paste composition including the same, and a method of preparing the metal particles for an adhesive paste.

### 2. Description of the Related Art

Recently, with electronic devices miniaturized and highly functionalized, a large number of semiconductor devices have been highly integrated on a single substrate. In this regard, in order to reduce defects and performance degradation due to thermal damage of a semiconductor package or module, there may be a requirement for a material capable of being mounted at a low temperature of 200° C. or less. It is also may be required to produce a low-temperature mounting material having a uniform size that is applicable even to flexible display devices without degrading the performance of a semiconductor device. Therefore, there may be demand for metal particles for an adhesive paste that have a uniform size as a low-temperature mounting material.

### SUMMARY

Provided are metal particles for an adhesive paste, including metal particles having a core-shell structure in various forms, do not aggregate, and have a uniform size.

Provided is a solder paste composition including the metal particles.

Provided is a method of preparing the metal particles for an adhesive paste.

Additional aspects will be set forth in part in the description which follows and, in part, will be apparent from the description, or may be learned by practice of the presented embodiments of the disclosure.

According to an embodiment, provided are metal particles for an adhesive paste. The metal particles may have a core-shell structure. The metal particles may include: a core including one or more metal materials; and a shell on part or an entirety of the core and including one or more metal materials. The one or more metal materials of the core may have a melting point higher than that of the one of more metal materials of the shell. An intermetallic compound can be formed between the one or more metal materials of the core and the one or more metal materials of the shell. A ratio (D90/D10) of the 90% cumulative mass particle size distribution (D90 size) to a 10% cumulative mass particle size distribution (D10 size) in a particle size distribution of the metal particles may be 1.22 or less.

In some embodiments, the metal particles may have a size of less than 100 μm.

In some embodiments, the shell may have a thickness of 10 nm to less than 100 μm.

In some embodiments, a cross-section of the metal particles may have a circular shape, an oval shape, a rectangular shape, a square shape, a pentagonal shape, a hexagonal shape, or a higher polygonal shape.

In some embodiments, an aspect ratio of a height to length of a cross-section of the core may be 0.5 to 4.

In some embodiments, the shell may be a monolayer or a multilayer of two or more layers.

In some embodiments, a void may not be present in an interfacial region between the core and the shell.

In some embodiments, a barrier layer may be further included between the core and the shell.

In some embodiments, the barrier layer may include nickel.

In some embodiments, the core may include a metal material selected from tin, nickel, copper, gold, silver, germanium, antimony, aluminum, titanium, palladium, zinc, or an alloy thereof.

In some embodiments, the shell may include a metal material selected from indium, gallium, silver, bismuth, zinc, or an alloy thereof.

In some embodiments, the core may include copper, and the shell may be a monolayer or multilayer structure of indium, silver, or a combination thereof.

In some embodiments, the core may include a tin-silver-copper alloy, and the shell may be a monolayer or multilayer structure of tin, bismuth, or a combination thereof.

According to another embodiment, a method of preparing the metal particles for an adhesive paste is provided. The method may include defining, on a first photoresist layer formed on a substrate, a region where core-shell metal particles are to be formed, by exposure with a first mask; forming a multilayer structure consisting of a first shell layer-core layer-second shell layer by applying a first shell metal material, a core metal material, and a second shell metal layer on the region where the core-shell metal particles are to be formed; and developing the multilayer structure to prepare the core-shell metal particles.

In some embodiments, in the forming the multilayer structure, a first shell metal material, a core metal material, and a second shell metal layer may be sequentially applied on the region where the core-shell metal particles are to be formed, to form the multilayer structure consisting of the first shell layer-core layer-second shell layer.

In some embodiments, the forming the multilayer structure may include: applying, on the region where the core-shell metal particles are to be formed, a first shell metal material and a core metal material to form a first multilayer structure comprising of a first shell layer-core layer; forming a second photoresist layer on the first multilayer structure and defining a region where a second multilayer structure comprising of a first shell layer-core layer-second shell layer is to be formed, by exposure with a second mask on the second photoresist layer; and applying, on the region where the second multilayer structure is to be formed, a second shell metal material to form the multilayer structure comprising of the first shell layer-core layer-second shell layer.

In some embodiments, the exposure may be performed with ARF (193 nm), KrF (248 nm), ArF+ immersion (38 nm), extreme ultraviolet (EUV, 13.5 nm), vacuum ultraviolet (VUV), e-beams, X-rays, or ion beams.

In some embodiments, the first shell metal material and the second shell metal material may be a same material or different.

In some embodiments, the core-shell metal particles may be prepared to have a variable size of less than 100 μm.

According to another embodiment, a method of preparing the metal particles for an adhesive paste is provided. The method may include defining, on a first photoresist layer formed on a substrate, a region where core-shell metal particles are to be formed, by exposure with a first mask; forming a core by applying core metal material on a region where a core is to be formed and performing exposure and development; forming a second photoresist layer on the core and defining, on the second photoresist layer, a region where a shell is to be formed, by exposure with a second mask that is thicker than the thickness of the first mask; and applying, on the region where a shell is to be formed, a shell metal material and performing development to prepare the above-described core-shell metal particles.

In some embodiments, the thickness of the second mask may be thicker than a thickness of the first mask by an amount in a range of 10 nm to less than 100 μm.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic view showing metal particles for an adhesive paste having a core-shell structure according to an embodiment;

FIG. 2 is a particle size distribution graph of metal particles for an adhesive paste according to an embodiment;

FIGS. 3A to 3F are schematic views showing the shapes of metal particles for an adhesive paste having a variety of cross-sections and aspect ratios according to embodiments;

FIG. 4 is a schematic view showing a solder paste including metal particles according to an embodiment;

FIG. 5 is a flow diagram illustrating a method of preparing metal particles for an adhesive paste according to an embodiment.

FIG. 6 is a flow diagram illustrating a method of preparing the metal particles for an adhesive paste according to another embodiment; and

FIGS. 7A and 7B are schematic views showing areas open by exposure when preparing metal particles for an adhesive paste that have a circular or hexagonal cross-section, respectively.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, metal particles for an adhesive composition according to embodiments, a solder paste composition including the metal particles, and a method of preparing the metal particles for an adhesive paste according to embodiments will be described in detail with reference to the appended drawings. Accordingly, it should be apparent to those skilled in the art that the following embodiments are provided for illustration purpose only and not for limiting the present disclosure, and the scope of the inventive concepts is defined only by the appended claims and their equivalents.

Hereinafter, it will also be understood that when an element is referred to as being “on” or “above” another element, it can be “directly on and in contact” with the other element, or “in non-contact” with intervening elements thereon.

As used herein, the singular forms “a”, “an” and “the” are intended to include the plural forms as well, unless the context clearly indicates otherwise. When a portion is referred to as “comprising” or “including” an element, it means that, unless stated specifically otherwise, another element can further be included; rather than excluded.

The term “combination” as used herein includes a mixture, an alloy, a reaction product, and the like, unless stated specifically otherwise.

The term “size” as used herein in association with particles is defined as follows according to cross-sectional shapes of the particles. For example, when the cross-section of particles is “circular,” the “size” means the “diameter” of the particles. For example, when the cross-section of particles is “elliptical,” the “size” means the length of the major axis. For example, when the cross-section of particles is “rectangular,” the “size” means the length of the longest side. For example, when the cross-section of particles is “pentagonal, or hexagonal or higher polygonal,” the “size” means “the length of one side.”

The term “cross-sectional length” as used herein in association with particles is defined as follows according to cross-sectional shapes of the particles. For example, when the cross-section of particles is “circular,” the “cross-sectional length” means the “diameter” of the particles. For example, when the cross-section of particles is “elliptical,” the “cross-sectional length” means the length of the major axis. For example, when the cross-section of particles is “rectangular,” the “cross-sectional length” means the length of the longest side. For example, when the cross-section of particles is “pentagonal, or hexagonal or higher polygonal,” the “cross-sectional length” means “the length of one side.”

Although the terms “first”, “second”, etc., may be used herein to describe various elements and/or components, these elements and/or components should not be limited by these terms. These terms are used only to distinguish one component from another, not for purposes of limitation.

As used herein, the term “or” means “and/or,” unless stated otherwise. As used herein, the terms “an embodiment”, “embodiments”, and the like indicate that specific elements described in connection with embodiments are included in at least one embodiment described herein and may or may not be present in other embodiments. In addition, it should be understood that the described elements may be combined in any suitable manner in various embodiments. Unless otherwise defined, technical and scientific terms used herein have the same meaning as commonly understood by one or ordinary skill in the art to which this application belongs. All patents, patent applications, and other cited references are incorporated herein by reference in their entirety. However, in the event of any conflict or inconsistency between terms used herein and terms of the cited references incorporated herein, the terms used in this specification take precedence over the terms of the cited references. Although specific embodiments and implementations have been described herein, all alternatives, modifications, variations, improvements, and substantial equivalents that were or are unpredictable may be made by the applicant or those skilled in the art. Accordingly, the appended claims as filed and as they may be amended are intended to embrace all such alternatives, modification, variations, improvements, and substantial equivalents.

In general, solders that are used in semiconductor packaging processes are a core material that electrically connects a circuit board or the like to various parts. The metal constituting the solder represents a melting point of about 60° C. to 400° C. according to the combination of components. When a solder including a high-melting point metal of 200° C. or more is applied to a highly integrated semiconductor package or a thin semiconductor package, the circuit board may undergo warpage or stretch due to the difference in coefficient of thermal expansion (CTE) between the circuit board and a die. At this time, tensile stress and compressive stress exert on upper and lower portions of the circuit board, respectively, thus causing damage to a solder bonding portion.

Considering this point, there may be a demand for a low-melting point adhesive paste that lowers, while using solders including a high-melting point metal of 200° C. or more, a processing temperature at a substrate side to 200° C. or less and at the same time reduces and/or minimizes a difference in physical properties from those of the solders.

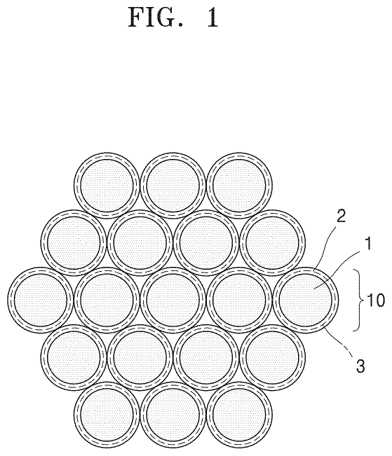

FIG. 1 is a schematic view showing metal particles for an adhesive paste that have a core-shell structure according to an embodiment.

As shown in FIG. 1, metal particles for an adhesive paste according to an embodiment include metal particles 10 having a core-shell structure that comprises: a core 1 including one or more metal materials; and a shell 2 formed on the core 1 and including one or more metal materials.

The metal material of the core 1 may have a melting point higher than that of the metal material of the shell 2. When the metal particles for an adhesive paste is used in a process of bonding a semiconductor package to a circuit substrate, only the metal material of the shell 2 in the metal particles for an adhesive paste may melt due to such a difference in melting point. As a result, an intermetallic compound (IMC) 3 can be formed between the metal material of the core 1 and the metal material of the shell 2 in the metal particles for an adhesive paste. Here, in the formed IMC, as shown in FIG. 1, unlike alloys, metal atoms occupy a constant position in a unit lattice of crystal, and thus have high hardness and brittleness. As a result, the metal particles for an adhesive paste according to an embodiment do not re-melt even in a subsequent heat treatment process at 400° C. or more. At the same time, when the metal particles for an adhesive paste are used as metal particles for a solder paste, the difference in physical properties such as toughness, Poisson's ratio, and the like may be reduced and/or minimized between the metal particles for an adhesive paste and the solder balls used.

In comparison with this, when a low-melting point adhesive paste, for example, a low-melting point solder paste, is applied on a substrate while solders including a high-melting point metal of 200° C. or more are used, at less than 100 cycles in thermal impact evaluation, defects in bonding portions such as ball shifts and cracks may occur, leading to defects in semiconductor packages or semiconductor modules.

A ratio (D90/D10) of the 90% cumulative mass particle size distribution (D90 size) to the 10% cumulative mass particle size distribution (D10 size) in the particle size distribution of the metal particles 10 having a core-shell structure may be 1.22 or less. For example, the ratio of D90/D10 may be 1.10 or less, or may be 1.02 or less. For example, the ratio of D90/D10 may be greater than 0 or may be 0.1 or greater, 0.2 or greater, 0.4 or greater, 0.6 or greater, 0.8 or greater, or 1 or greater.

The 50% cumulative mass particle size distribution (D50 size) in the particle size distribution of the metal particles 10 having a core-shell structure may be 110 nm. For example, the D50 size may be 105 nm or less, or 100 nm or less, or 98 nm or less, or 96 nm or less. For example, the D50 size may be greater than 0 nm, or 10 nm or more, or 20 nm or more, 30 nm or more, 40 nm or more, 50 nm or more, 60 nm or more, 70 nm or more, 80 nm or more, or 90 nm or more.

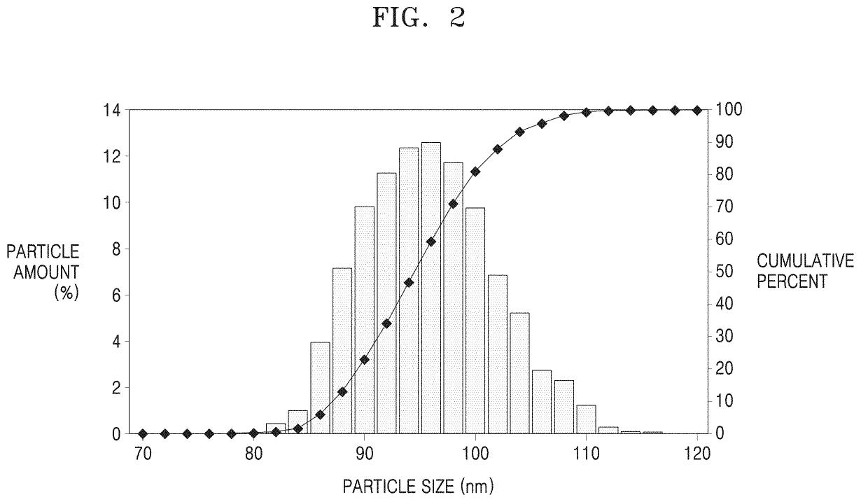

FIG. 2 is a particle size distribution graph of metal particles for an adhesive paste according to an embodiment. The metal particles for an adhesive paste according to an embodiment may be metal particles having a core-shell structure in which the core is tin and the shell is bismuth.

The metal particles having a core-shell structure may be prepared in the following manner.

A photoresist layer including polyhydroxystyrene as a base polymer is applied on a substrate to a thickness of hundreds of nanometers and exposed to a KrF excimer scanner to define a region where core-shell metal particles having a circular cross-section of about 100 nm is to be formed. The defined region is developed with tetramethylammonium hydroxide (TMAH), and a bismuth layer, a tin layer, and a bismuth layer are sequentially applied thereon to prepare core-shell metal particles having a circular cross-section of a size of about 100 nm. In other embodiments, the defined region may be subjected to a post exposure bake (PEB), instead of the development with TMAH.

As shown in FIG. 2, in the particle size distribution of the metal particles for an adhesive paste according to an embodiment, the 10% cumulative mass particle size distribution (D10 size) may be 87 nm, the D50 size may be 95 nm, and the D90 size may be 103 nm. A ratio of D90/D10 may be 1.18.

However, the ratio of D90/D10 and the D50 size are not limited to those as in FIG. 2. In the metal particles for an adhesive paste according to an embodiment, the ratio of D90/D10 and the D50 size may be appropriately controlled within a range of 1.22 or less and 110 nm or less, respectively, according to the size of the particles or/and a light source used for exposure, so as to provide a uniform particle size distribution.

The metal particles may have a size of less than 100 μm. For example, the size of the metal particles may be 0.01 μm to less than 100 μm, or may be 0.05 μm to 90 μm, or 1 μm to 80 μm, 1 μm to 60 μm, or 3 μm to 60 μm, or 5 μm to 60 μm, 7 μm to 60 μm, or 9 μm to 60 μm, or 10 μm to 50 μm, or 20 μm to 50 μm, or 25 μm to 45 μm. The metal particles having these micro sizes may be applicable to a highly integrated circuit or a thin circuit that gradually becomes more miniature.

The shell 2 may have a thickness of 10 nm to less than 100 μm. For example, the thickness of the shell 2 may be 50 nm to 90 μm, or 100 nm to 80 μm, or 100 nm to 70 μm, or 100 nm to 60 μm, or 100 nm to 50 μm, or 100 nm to 40 μm, or 100 nm to 30 μm.

The cross-section of the metal particles may have a circular, an oval, a rectangular, a square, a pentagonal, or a hexagonal or higher polygonal (e.g., a polygonal shape having more than 6 sides) shape.

An aspect ratio of the height to length of a cross-section of the core may be 0.5 to 4.

The shell hay be a monolayer or a multilayer of two or more layers.

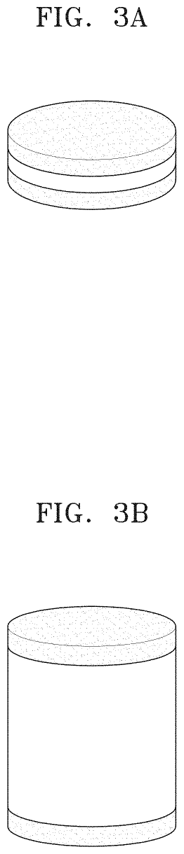

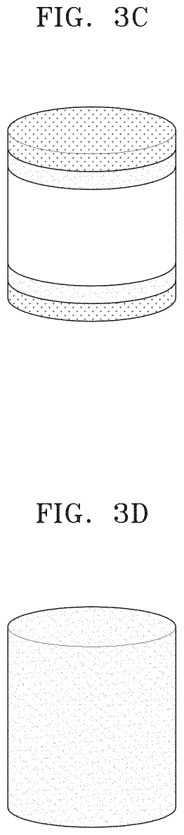

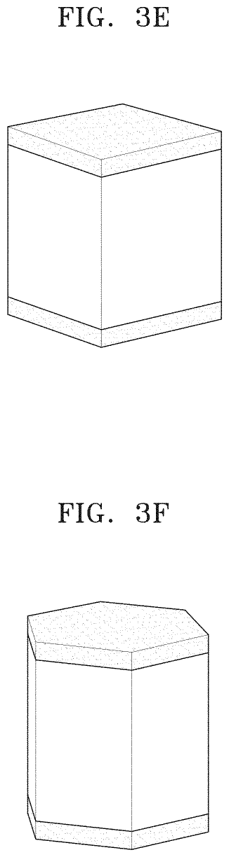

FIGS. 3A to 3F are schematic views showing the shapes of metal particles for an adhesive paste having a variety of cross-sections and aspect ratios according to embodiments.

Referring to FIGS. 3A to 3D, the metal particles for an adhesive paste according to embodiments may be in the form of metal particles having a circular cross-section and various aspect ratios. FIGS. 3A and 3B show that each of the upper and lower layers is a shell layer coated as a monolayer. FIG. 3C shows that each of the upper and lower layers is a shell layer coated as double layers. FIG. 3D shows that each of the upper and side surfaces, other than the lower surface, is a shell layer coated as a monolayer. FIGS. 3E and 3F show that metal particles for an adhesive paste according to embodiments may have a rectangular cross-section and a hexagonal cross-section, respectively, in which each of the upper and lower layers is a shell layer coated as a monolayer.

A void may not be present in an interface region between the core 1 and the shell 2. The metal particles having a core-shell structure without voids may enhance the brittleness and toughness of the bonding portion where the metal particles are used, even under high-temperature processes and external impact.

A barrier layer may be further included between the core 1 and the shell 2. The barrier layer can prevent the intermetallic compound (IMC) 3 from being formed between the core 1 and the shell 2. Diffusion may occur between the core 1 and the shell 2 during a process of bonding a semiconductor package to a circuit board. At this time, the barrier layer may reduce and/or minimize the probability that voids such as a diffusion layer may be present.

The barrier layer may include nickel.

For example, the core 1 may include metal materials such as tin, nickel, copper, gold, silver, germanium, antimony, aluminum, titanium, palladium, zinc, or an alloy thereof.

For example, the shell 2 may include metal materials such as indium, gallium, silver, bismuth, zinc, or an alloy thereof.

For example, the core 1 may include copper, and the shell 2 may be a monolayer or multilayer structure of indium, silver, or a combination thereof. For example, the core 1 may include copper, and the shell 2 may be an indium-coated monolayer layer structure on the core 1. For example, the core 1 may include copper, and the shell 2 may be a two-layer structure of indium and silver sequentially coated on the core 1.

For example, the core 1 may include a tin-silver-copper alloy, and the shell 2 may be a monolayer or multilayer structure of tin, bismuth, or a combination thereof. For example, the core 1 may include a tin-silver-copper alloy, or an alloy of tin, silver and copper with at least one metal selected from among nickel, copper, zinc, bismuth, and aluminum. For example, the core 1 may include Sn-3.0Ag-0.5Cu, Sn-1.0Ag-0.5Cu, Sn-4.0Ag-0.5Cu, Sn-1.2Ag-0.5Cu-0.05Ni-0.01Ge, or Sn-1.2Ag-0.5Cu-0.5Sb. However, embodiments are not limited thereto, the core 1 may include a tin-silver-copper alloy in various compositions, or a tin-silver-copper alloy in various compositions with at least one metal selected from among nickel, cobalt, zinc, bismuth, and aluminum.

For example, in the metal particles 10 having a core-shell structure, the core 1 may include Sn-3.0Ag-0.5Cu, and the shell 2 may be a monolayer structure coated with bismuth on the core 1. For example, in the metal particles 10 having a core-shell structure, the core 1 may include Sn-3.0Ag-0.5Cu, and the shell 2 may be a two-layer structure of bismuth and Sn58Bi sequentially coated on the core 1.

A solder paste composition according to another embodiment may include the metal particles as described above. The solder paste composition may include the metal particles as described above, and a binder.

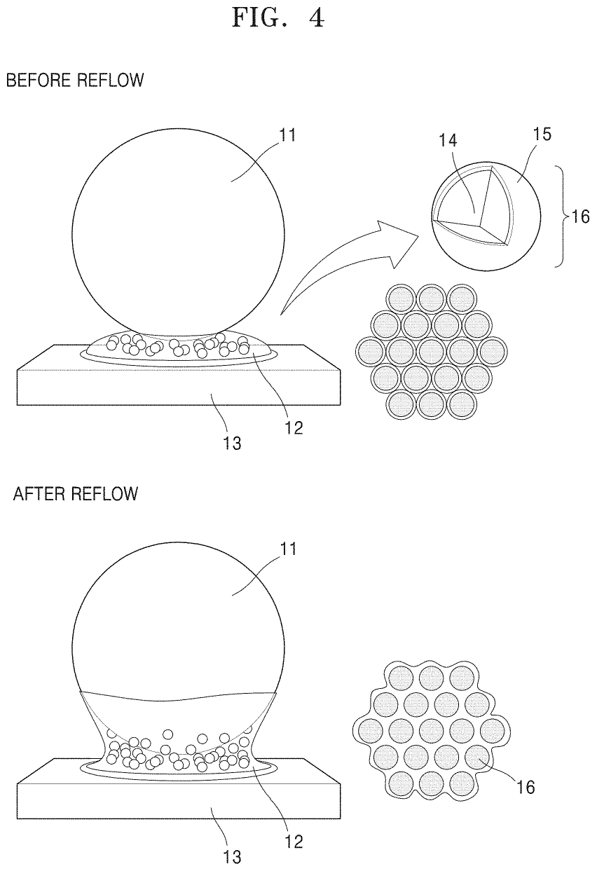

FIG. 4 is a schematic view showing a solder paste including metal particles according to an embodiment;

Referring to FIG. 4, metal particles 16 according to an embodiment are included in a solder paste composition 12 that bonds a substrate 13 to a solder ball 11. The metal particles 16 have a core-shell structure in which the metal material of a core 14 and the metal material of a shell 15 form an IMC. The core 14 of the metal particles may include a metal material having similar physical properties to those of the solder ball 11, in terms of crystal structure, toughness, Poisson's ratio, or the like. The shell 15 of the metal particles may include a metal material that melts at a low temperature and is uniformly coated around the core 14. In the solder paste composition 12 according to an embodiment, the metal particles 16 do not re-melt even in a subsequent heat treatment process at 400° C. or more, and may reduce and/or minimize the difference in physical properties such as toughness, Poisson's ratio, or the like between the metal particles 16 and the solder ball 11 used. As a result, even with external thermal impact and physical drop shock, any defect at a bonding portion such as a ball shift, cracks, and the like does not occur, causing no damage to a semiconductor package or the like.

The binder may impart a certain level of viscosity and sedimentation stability. For example, the binder may include one or more of a synthetic resin, rosin, fatty acids, and oils. The synthetic resin may include one or more of acryl, urethane, ester, ether, and epoxy, and is not limited thereto. The rosin may include one or more of an abietic acid, a hydrogenated rosin ester, a dehydrogenated rosin ester, and an acrylic modified rosin, but is not limited thereto. The hydrogenated rosin ester and dehydrogenated rosin ester may be formed by modification of abietic acid, and the acrylic modified rosin may be formed by modification of a double bond in rosin.

A solvent may be added to adjust viscosity. For example, the solvent may include one or more of glycol ethers and alcohols. A glycol ether-bases solvent may include one or more of propylene glycol mono butyl ether, ethylene glycol monohexyl ether, diethylene glycol monohexyl ether, diethylene glycol monobutyl ether, diethylene glycol dibutyl ether, ethylene glycol monobenzyl ether, diethylene glycol monobenzyl ether, and diethylene glycol mono 2-ethylhexyl ether, but is not limited thereto.

A method of preparing the metal particles for an adhesive paste according to another embodiment may include: defining, on a first photoresist layer formed on a substrate, a region where core-shell metal particles are to be formed, by exposure with a first mask; applying a first shell metal material, a core metal material, and a second shell metal layer on the region where the core-shell metal particles are to be formed, to form a multilayer structure comprising of a first shell layer, a core layer, and a second shell layer; and developing the multilayer structure to prepare the core-shell metal particles as described above.

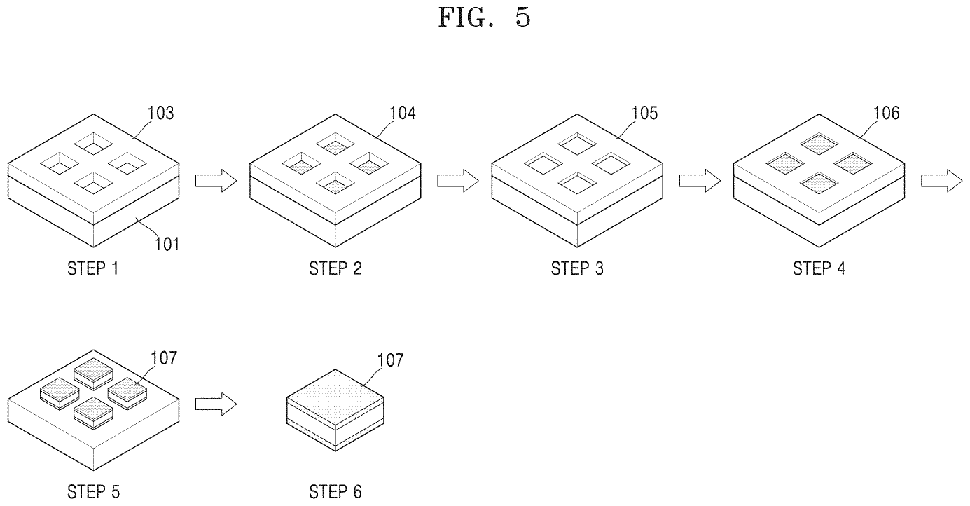

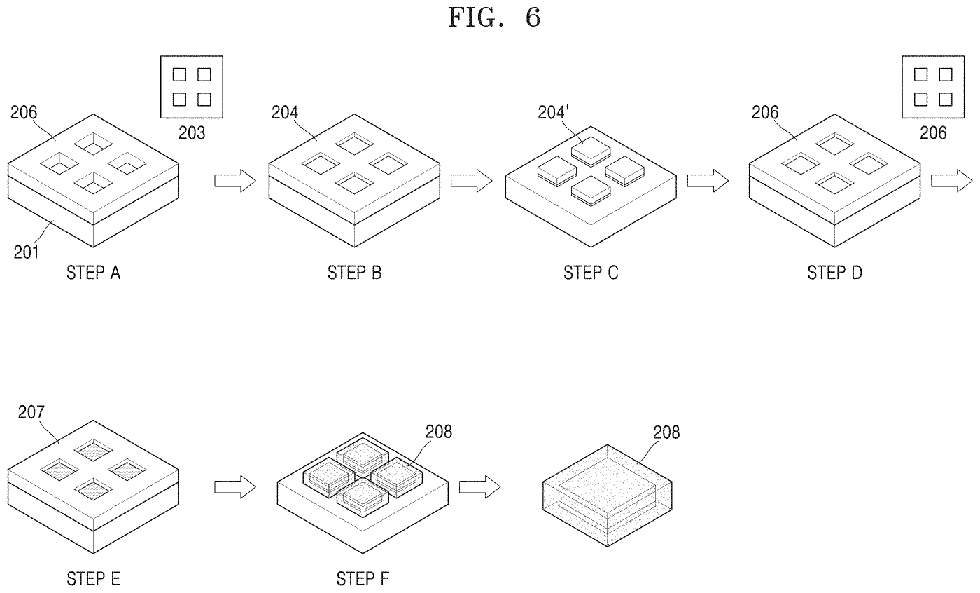

FIG. 5 is a flow diagram illustrating a method of preparing metal particles for an adhesive paste according to an embodiment.

Referring to FIG. 5, the method of preparing the metal particles for an adhesive paste according to an embodiment includes forming, on a photoresist layer formed on a substrate 101, a first mask 103 to define a region where core-shell metal particles are to be formed, through exposure (Step 1).

The photoresist layer is formed by applying a photoresist composition on the substrate 101. The substrate 101 may include a semiconductor substrate, such as a silicon substrate, a germanium substrate, a silicon-germanium substrate, a silicon-on-insulator (SOI) substrate, and a germanium-on-insulator (GOI) substrate. The substrate 101 may further include a well region including p-type or n-type impurities. The substrate 101 may include a silicon wafer. The surface of the substrate 101 may be treated with a water soluble material or a water insoluble material. The surface treatment may enable separation of the multilayer structure comprising of a first shell layer-core layer-second shell layer, which will be described later, from the substrate 101.

The photoresist composition is applied on the substrate 101 to form the photoresist layer. For example, the photoresist layer may be formed of a resist composition for a KrF excimer laser (248 nm), a resist composition for an ArF excimer laser (193 nm), a resist composition for an F2 excimer laser (157 nm), or a resist composition for extreme ultraviolet (EUV, 13.5 nm). However, embodiments are not limited thereto, and the photoresist layer may be formed of any resist composition for every light source available in the art. The photoresist composition may be coated using any known method, such as spin coating, die coating, or bar coating. When the photoresist composition is applied, prebake may be performed to evaporate the solvent included in the composition.

The first mask 103 is arranged on the formed photoresist layer, followed by exposure with the first mask 103. After the exposure, the region where core-shell metal particles are to be formed is defined using development with an alkali aqueous solution or a post-exposure bake (PEB). The exposure may be performed with ArF (193 nm), KrF (248 nm), ArF+ immersion (38 nm), EUV (13.5 nm), vacuum ultraviolet (VUV), E-beams, X-rays, or ion beams. Examples of the alkali aqueous solution for the development process include, but are not limited to, a 2.38-wt % TMAH aqueous solution.

A first shell metal material, a core metal material, and a second shell metal material are sequentially applied on the region where the core-shell metal particles are to be formed, to form the multilayer structure comprising of a first shell layer-core layer-second shell layer (Steps 2-4).

A first shell layer 104 is formed by coating a first shell metal material constituting the core-shell metal particles on the region where the core-shell metal particles are to be formed (Step 2). A core layer 105 is formed by coating a core metal material constituting the core-shell metal particles on the first shell layer 104 (Step 3). A second shell layer 106 is formed by coating a second shell metal material constituting the core-shell metal particles on the formed core layer 105 (Step 4). A method of coating the first shell layer 104, the core layer 105, and the second shell layer 106 are not limited, and any method known in the art, for example, any wet or dry coating method, plating method, or/and deposition method may be used. The first shell metal material and the second shell metal material may be the same or different. For example, the first shell layer 104 may have a thickness of 10 nm to less than 10 μm. For example, the thickness of the second shell layer 106 may be the same as or greater than the thickness of the first shell layer 104. The core layer 105 may have a thickness of about 0.01 μm to 100 μm. Steps 2 to 4 may further include stacking a barrier layer, although not shown. For example, the barrier layer may have a thickness of, for example, 1 nm to 1000 nm. However, embodiments are not limited thereto.

In other embodiments, although not illustrated, the forming of the multilayer structure comprising of the first shell layer-core layer-second shell layer may include: applying a first shell material and a core metal material on the region where the core-shell metal particles are to be formed, to form a first multilayer structure consisting of a first shell layer-core layer; forming a second photoresist layer on the first multilayer structure, followed by exposure with a second mask on the second photoresist layer to define a region where a second multilayer structure comprising of a first shell layer-core layer-second shell layer is to be formed; and applying a second shell metal material on the region where the second multilayer structure is to be formed, to form the multilayer structure consisting of the first shell layer-core layer-second shell layer (Steps 2-4).

By developing the multilayer structure comprising of the first shell layer-core layer-second shell layer (Step 5), core-shell metal particles 107 as described above are prepared (Step 6).

Although the core-shell metal particles 107 shown in FIG. 5 are particles with a core having a rectangular cross-section and shell layers coated only on the upper and lower surfaces of the core, embodiments are not limited thereto. In other embodiments, the core-shell metal particles prepared using steps 2-4 as described above may be particles in which all the surfaces other than the lower surface of the core is coated with a shell layer. The core-shell metal particles 107 may be prepared to have a variable size less than 100 μm. The cross-section of the core-shell metal particles 107 may have a circular, oval, square, pentagonal, or hexagonal or higher polygonal shape, other than a rectangular shape as described above. The core-shell metal particles 107 may have an aspect ratio of 0.5 to 4, which is a height to length ratio of the core cross-section.

The prepared core-shell metal particles 107 may be a preform. Through a reflow process of the preform together with an adhesive paste, for example, a solder paste, at 200° C. or less, the metal material of the shell in the core-shell metal particles melts down, thus enabling a uniform bonding with a circuit board without defects.

A method of preparing the metal particles for an adhesive paste according to another embodiment may include: defining a region where a core is to be formed, by exposure with a first mask on a first photoresist layer formed on a substrate; applying a core metal material on the region where a core is to be formed, followed by exposure and development to form a core; forming a second photoresist layer on the core, and defining a region where a shell is to be formed, by exposure with a second mask on the second photoresist layer, the second mask having a larger thickness than that of the first mask; and applying a shell metal material on the region where a shell is to be formed, followed by exposure and development to form a shell, thereby preparing the core-shell metal particles as described above.

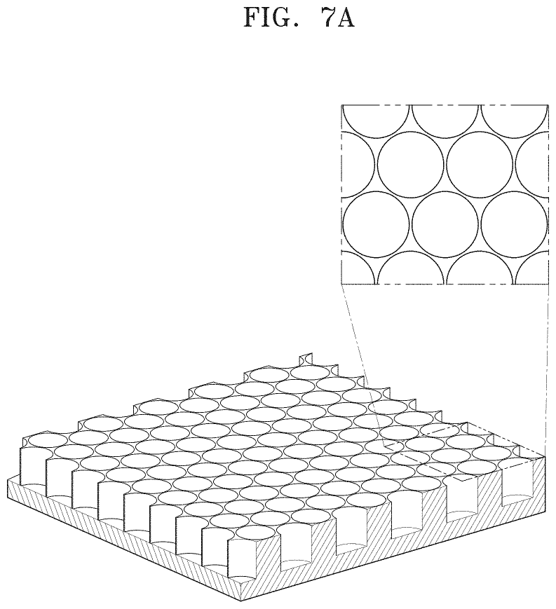

FIG. 6 is a flow diagram illustrating a method of preparing metal particles for an adhesive paste according to another embodiment.

Referring to FIG. 6, the method of preparing metal particles for an adhesive paste according to an embodiment includes defining a region where a core is to be formed, by exposure with a first mask 203 on a first photoresist layer formed on a substrate 201 (Step A).

The first photoresist layer is formed by applying a first photoresist composition on the substrate 201. Types of the substrate, methods of coating the first photoresist composition, the thickness of each layer, the exposure process, and the development process are the same as described above, and thus, descriptions thereof will be omitted.

A core layer 204 is formed by applying a core metal material on the region where a core is to be formed, and then exposed and developed to form a core 204′ (Steps B-C). In addition, although not illustrated, the method may further include, before the formation of the core layer 204, applying a first shell metal material to form a first shell layer. The core metal material, the thickness of the core layer, and the exposure and development processes may be the same as described above, and thus, descriptions thereof will be omitted.

A second photoresist layer is formed on the core 204′ and then exposed with a second mask that has a larger thickness than that of the first mask 203, to define a region where a shell is to be formed (Step D). The thickness of the second mask 206 may 10 nm to 100 μm thicker than the thickness of the first mask 203. A method of coating the second photoresist composition and the thickness of each layer may be the same as described above, and thus, descriptions thereof will be omitted.

By coating a shell metal material on the region where a shell is to be formed, to form a shell layer 207 and developing the shell layer 207 (Step E), core-shell metal particles 208 as described above are prepared (Step F).

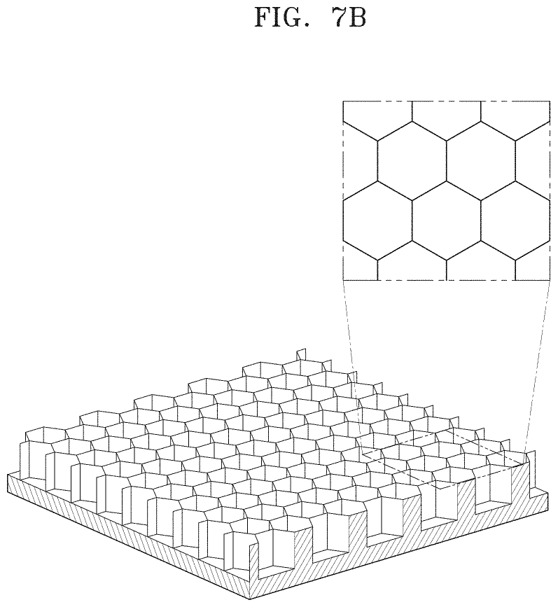

Although the core-shell metal particles 208 shown in FIG. 7 are particles with a core having a rectangular cross-section and a shell layer coated on all the upper and side surfaces other than the lower surface of the core, embodiments are not limited thereto. The core-shell metal particles 208 may be prepared to have a variable size less than 100 μm. The cross-section of the core-shell metal particles 208 may have a circular, oval, square, pentagonal, or hexagonal or higher polygonal shape, other than a rectangular shape as described above. The core-shell metal particles 208 may have an aspect ratio of 0.5 to 4, which is a height to length ratio of the core cross-section.

The prepared core-shell metal particles 208 may be a preform. Through a reflow process of the preform together with an adhesive paste, for example, a solder paste, at 200° C. or less, the metal material of the shell in the core-shell metal particles 208 melts down, thus enabling a uniform bonding with a circuit board without defect.

The core-shell metal particles 107 and 208 as prepared above may be used in next-generation display devices, other than semiconductors, for example, for a flexible display that requires a low-temperature mount, a wearable display, or a stretchable display.

FIGS. 7A and 7B are schematic views showing areas open by exposure when preparing metal particles for an adhesive paste that have a circular or hexagonal cross-section, respectively.

Referring to FIGS. 7A and 7B, assuming that the inter-particle distance and the particle size of the metal particles for an adhesive paste are 1 μm and 50 μm, respectively, the open area ratio according to Equation 1, which is obtained by exposure to form the metal particles for an adhesive paste that have a hexagonal cross-section, is larger by about 9% than the open area ratio obtained by exposure to form the metal particles for an adhesive paste that have a circular cross-section. From this, it is believed that forming metal particles for an adhesive paste that have a hexagonal cross-section is advantageous in terms of yield, as compared with forming metal particles for an adhesive paste that have a circular cross-section.

Open area ratio (%)=[(Area open by exposure)/(Total area of exposure)]×100 <Equation 1>

Up to this point, example embodiments have been described and illustrated in the drawings in order to help understanding of inventive concepts. However, these embodiments should be understood that they are only for illustrative purposes, not for limitation. It should be understood that inventive concepts are not limited to the presented embodiments. This is because various other modifications may be made as understood by those skilled in the art.

As described above, according to the one or more embodiments, provided are metal particles for an adhesive paste that have a core-shell structure in various forms, do not aggregate, and have a uniform size. The metal particles for an adhesive paste may be applied to a paste for bonding a substrate (circuit board) and electronic device components, for example, to an adhesive paste for a semiconductor package. The metal particles for an adhesive paste enable mounting a semiconductor device onto a substrate (circuit board) at a low temperature, and thus may reduce defects due to thermal damage of semiconductor modules, and performance degradation.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. Metal particles for an adhesive paste, comprising metal particles having a core-shell structure comprising:
a core including one or more metal materials; and
a shell on part or an entirety of the core and including one or more metal materials,
wherein the one or more metal materials of the core has a melting point higher than that of the one or more metal materials of the shell,
an intermetallic compound is capable of being formed between the one or metal materials of the core and the one or more metal materials of the shell, and
a ratio (D90/D10) of a 90% cumulative mass particle size distribution (D90 size) to a 10% cumulative mass particle size distribution (D10 size) in a particle size distribution of the metal particles is 1.22 or less.

2. The metal particles of claim 1, wherein the metal particles have a size of less than 100 μm.

3. The metal particles of claim 1, wherein the shell has a thickness of 10 nm to less than 100 μm.

4. The metal particles of claim 1, wherein a cross-section of the metal particles has a circular shape, an oval shape, a rectangular shape, a square shape, a pentagonal shape, a hexagonal shape, or a higher polygonal shape.

5. The metal particles of claim 1, wherein an aspect ratio of a height to length of a cross-section of the core is 0.5 to 4.

6. The metal particles of claim 1, wherein the shell is a monolayer or a multilayer of two or more layers.

7. The metal particles of claim 1, wherein a void is not present in an interface region between the core and the shell.

8. The metal particles of claim 1, further comprising:
a barrier layer between the core and the shell.

9. The metal particles of claim 8, wherein the barrier layer includes nickel.

10. The metal particles of claim 1, wherein the core includes a metal material selected from tin, nickel, copper, gold, silver, germanium, antimony, aluminum, titanium, palladium, zinc, or an alloy thereof.

11. The metal particles of claim 1, wherein the shell includes a metal material selected from indium, gallium, silver, bismuth, zinc, or an alloy thereof.

12. The metal particles of claim 1, wherein
the core includes copper, and
the shell has a monolayer or multilayer structure of indium, silver, or a combination thereof.

13. The metal particles of claim 1, wherein
the core includes a tin-silver-copper alloy, and
the shell has a monolayer or multilayer structure of tin, bismuth, or a combination thereof.

14. A solder paste composition comprising:
the metal particles according to claim 1.

15. A method of preparing the metal particles for an adhesive paste of claim 1, the method comprising:
defining, on a first photoresist layer formed on a substrate, a region where core-shell metal particles are to be formed, through exposure with a first mask;
forming a multilayer structure consisting of a first shell layer-core layer-second shell layer by applying a first shell metal material, a core metal material, and a second shell metal material on the region where the core-shell metal particles are to be formed, to; and
developing the multilayer structure to prepare core-shell metal particles.

16. The method of claim 15, wherein, in the forming the multilayer structure, a first shell metal material, a core metal material, and a second shell metal material are sequentially applied on the region where the core-shell metal particles are to be formed, to form the multilayer structure consisting of the first shell layer-core layer-second shell layer.

17. The method of claim 15, wherein the forming the multilayer structure comprises:
applying, on the region where the core-shell metal particles are to be formed, a first shell metal material and a core metal material to form a first multilayer structure comprising of a first shell layer-core layer;
forming a second photoresist layer on the first multilayer structure and defining a region where a second multilayer structure comprising of a first shell layer-core layer-second shell layer is to be formed, by exposure with a second mask on the second photoresist layer; and
applying, on the region where the second multilayer structure is to be formed, a second shell metal material to form the multilayer structure comprising of the first shell layer-core layer-second shell layer.

18. The method of claim 15, wherein the exposure is performed with ArF (193 nm), KrF (248 nm), ArF+ immersion (38 nm), EUV (13.5 nm), vacuum ultraviolet (VUV), E-beams, X-rays, or ion beams.

19. The method of claim 15, wherein the first shell metal material and the second shell metal material are a same material or different.

20. The method of claim 15, wherein the core-shell metal particles are prepared to have a variable size of less than 100 μm.

21. A method of preparing the metal particles for an adhesive paste of claim 1, the method comprising:
defining, on a first photoresist layer formed on a substrate, a region where core-shell metal particles are to be formed, through exposure with a first mask;
forming a core by applying a core metal material on a region where a core is to be formed, and performing exposure and development;
forming a second photoresist layer on the core and defining, on the second photoresist layer, a region where a shell is to be formed, by exposure with a second mask that is thicker than a thickness of the first mask; and
applying, on the region where the shell is to be formed, a shell metal material, followed by development to prepare the core-shell metal particles.

22. The method of claim 21, wherein a thickness of the second mask is thicker than a thickness of the first mask by an amount in a range of 10 nm to 100 μm.

23. The method of claim 21, wherein the exposure is performed with ArF (193 nm), KrF (248 nm), ArF+ immersion (38 nm), EUV (13.5 nm), vacuum ultraviolet (VUV), E-beams, X-rays, or ion beams.

24. The method of claim 21, wherein the core-shell metal particles are prepared to have a variable size of less than 100 μm.
